(19) United States
(12) Patent Application Publication
(10) Pub. No.: US 2015/0187748 A1
(43) Pub. Date: Jul. 2, 2015

(54) ELECTROSTATIC DISCHARGE SHUNT FOR SEMICONDUCTOR DEVICES

(71) Applicant: Emcore Corporation, Albuquerque, NM (US)

(72) Inventor: Jia-Sheng Huang, South Pasadena, CA (US)

(73) Assignee: Emcore Corporation, Albuquerque, NM (US)

(21) Appl. No.: 14/146,722

(22) Filed: Jan. 2, 2014

(51) Int. Cl. H01L 27/02; H01L 23/60

(52) U.S. Cl. CPC H01L 27/0248; H01L 23/60

(57) ABSTRACT

A semiconductor device or an integrated circuit formed on a substrate with shunt disposed on the substrate in parallel with the device or circuit and designed to form a closed circuit or discharge path when the device is subjected to an electrostatic discharge pulse.

### BACKGROUND OF THE INVENTION

1. Field of the Invention

The field of the invention relates to semiconductor devices and more particularly to improving the reliability of such devices by providing devices and circuitry protecting them from electrostatic discharge (ESD) pulses or electrical overstress (EOS).

2. Description of the Related Art

The use of electro-static discharge (ESD) protection devices for integrated circuits is known in the prior art. For example, U.S. Pat. No. 6,794,715 to Lui et al. provides a circuit structure for ESD protection and methods for making the circuit structure. Specifically, a p-n junction is formed between a first diffusion region and a second diffusion region that breaks down in response to an ESD pulse, thereby causing discharge current to harmlessly flow across a portion of the substrate.

Like any semiconductor device, susceptibility to ESD damage is an important manufacturing and reliability issue. A semiconductor device or integrated circuit (IC) may be exposed to ESD from many sources, such as static electricity generated by automated assembly equipment or the human body. A major source of ESD exposure for such devices is from the human body. For instance, a charge of about 0.6 .mu.C can be induced on a human body with a body capacitance of 150 pF. When the charged human body comes into contact with the pins of an IC, an electrical path through the IC may result and the applied current may cause damage to the individual devices in the IC. Such a discharge event is typically simulated by reliability engineers using a Human Body Model (HBM), which, in one example, includes a 100-150 pF capacitor discharged through a switching component and a 1.5 kOhm resistor into an IC.

A discharge similar to the HBM event can also occur during the manufacturing or assembly process when the IC comes into contact with a charged conductive object, such as a metallic tool or fixture. This is typically modeled by a so-called machine model (MM). In one example, the MM includes a 200 pF capacitor discharged directly into the IC. The MM is sometimes referred to as the worst-case HBM.

The transfer of charge from the IC is also an ESD event. The IC may become charged, for example, from sliding down a feeder in an automated assembler. If it then contacts a metal insertion head or other conductive surface, a rapid discharge may occur from the device to the metal object. This event is typically modeled by a Charged Device Model (CDM). Because the IC itself becomes charged in a CDM event, and discharges to ground, the discharge current flows in the opposite direction in the IC as compared to that of an HBM event or MM event. Although the duration of the CDM discharge is typically very short, often less than one nanosecond, the peak current can reach several tens of amperes. Thus, the CDM discharge can be more destructive than the HBM event for some ICs.

Many commonly used ICs contain elements, such as transistors, resistors, capacitors and interconnects, that can fail when an ESD event occurs thereby affecting the quality, reliability, yield, delivery and cost of ICs. As a result, IC product failure from ESD is an important concern in the semiconductor microelectronics industry; and industry standards require that IC products withstand a minimum level of ESD. To meet this requirement, ESD protection circuitry is generally build into the input, output, and/or power supply circuits of an IC.

The ability to produce workable ESD protection structures depends upon the interrelationship of IC's topology, the design layout, the circuit design, and the fabrication process. Various circuit designs and layouts have been proposed and implemented for protecting ICs from ESD.

One particular type of semiconductor device which is of concern for ESD issues is the VCSEL. VCSEL devices are susceptible to electrostatic discharge events because of smaller active volume. ESD events occur where a static charge builds up and is subsequently discharged. When the static charge discharges through a VCSEL, it may be catastrophically damaged. U.S. Pat. No. 6,185,240 to Jiang et al. describes ESD protection for VCSEL devices in which a VCSEL and diode are fabricated on a common substrate and where the diode is in parallel reverse orientation to the VCSEL. When a reverse biased ESD event is applied to the VCSEL, the parallel connected diode provides a very low resistance path to quickly drain off the charge before it can damage the VCSEL. Since the reverse biased ESD damage threshold is typically lower than the forward biased ESD damage threshold, the Jiang solution increases the VCSEL ESD threshold tolerance damage level.

Still other means of protecting ICs from ESD, EOS or CDM is through the use of fusible links or fuse networks connected between a power supply and ground, such as described in U.S. Pat. No. 6,762,918 to Voldman. In this case the fuse networks are used for enabling/disabling circuits/circuit blocks.

In order to make the fusible link/network useful, the prior art has assumed that some type of circuitry must be used to determine the state of the fuse (e.g., open/closed). In addition, circuit elements are often intentionally blown (via electrical means) or optical means (via laser energy) for purposes of programming a circuit. In these cases, the techniques used for blowing the circuit elements can induce enough energy to lead to EOS or ESD failure of the circuitry used to read the state of the fuse (i.e., the fuse state circuitry). For example, the electrical current to open a circuit element or fuse can lead to currents which cause failure of the fuse element and the fuse state circuitry at the same time. In further example, the use of a laser to blow a circuit element can lead to conversion of optical to thermal energy where the thermal energy can lead to an electrical current, forming a pulsed electrical spike propagating into the fuse state circuitry.

Prior to the present disclosure, there has not been simple, effective, and easily implemented technique directed to protecting semiconductor devices from EOS. Accordingly, a need exists for better methods of protecting semiconductor devices.

### SUMMARY OF THE INVENTION

### 1. Objects of the Invention

It is the object of this disclosure to provide an integrated shunt in a semiconductor device to enable electrostatic discharge protection in a semiconductor device.

It is another object of the disclosure to provide an adjustable electrically resistive element for use in a semiconductor device circuit.

It is another object of the disclosure to provide a continuously electronically controllable resistive element in a semiconductor device.

It is another object of the disclosure to provide a silicide line in a silicon semiconductor device to enable a continuously electrically controllable adjustment of a device characteristic or parameter by varying the current through the line.

Some implementations of the present disclosure may incorporate of implement fewer of the aspects and features noted in the foregoing objects.

### 2. Features of the Disclosure

Briefly, and in general terms, the present disclosure provides a semiconductor device or an integrated circuit formed on a substrate with shunt disposed on the substrate in parallel with the device or circuit and designed to form a closed circuit or discharge path when the device is subjected to an electrostatic discharge pulse.

In another aspect, the present disclosure provides semiconductor device including a n-conductivity type silicon semiconductor substrate having a surface including an active semiconductor device; a p-conductivity type region disposed in the semiconductor substrate having a first end and a second end forming a channel there between; a first electrical terminal composed of nickel or cobalt disposed on the first end semiconductor substrate; a second electrical terminal composed of nickel or copper disposed on the second end semiconductor substrate; and wherein an electromigration-induced silicide line is formed in the channel between the first and the second electrical terminal when the applied current to the terminals increases.

In some embodiments, the channel is between 150 and 200 micrometers long and between 1 and 10 micrometers wide.

In some embodiments, the channel is between 150 and 200 micrometers long and between 0.5 and 1.5 micrometers wide.

In some embodiments, the applied current is between 60 and 90 mA.

In some embodiments, the applied current is between 70 and 80 mA.

In some embodiments, the applied current is about 80 mA.

In some embodiments the silicide line is between 1 and 2 microns in width, and less than one micron in depth.

In some embodiments the silicide line is between 0.5 and 1 microns in width, and less than one-half micron in depth.

In some embodiments the silicide line is about 0.5 micron in width, and about 0.5 micron in depth.

In another aspect, the present disclosure provides a semiconductor device comprising a semiconductor substrate having a surface including an active circuit; a first electrical test point disposed in the circuit on the semiconductor substrate; a second electrical test point disposed in the circuit on the semiconductor substrate; and a shunting element composed of p+ conductivity type silicon disposed on the semiconductor substrate having a first end coupled to the first electrical test point and a second end coupled to the second test point, the shunting element having a first resistance range for current flow through the element up to a predetermined current threshold, and operate so that if the current flow through the shunting element exceeds the predetermined threshold, the resistance of the shunting element will drop substantially below that of the first resistance range.

In some embodiments, the shunting element is a channel disposed in the semiconductor substrate in which is formed an electromigration induced conductive silicide line as a function of applied current through the channel.

In some embodiments, the device, further comprises a first electrical terminal composed of nickel or copper disposed at the first test point and a second electrical terminal composed of nickel or copper disposed at the second test point.

In some embodiments, the semiconductor substrate is composed of n conductivity type silicon.

In another aspect, the present disclosure provides a semiconductor device comprising a semiconductor substrate having a surface including an active circuit; a first electrical terminal of a first polarity disposed in the circuit on the semiconductor substrate; a second electrical terminal of a second polarity disposed in the circuit on the semiconductor substrate; and a shunting semiconductor region disposed on the semiconductor substrate in a parallel electrical circuit to the active circuit, the shunting semiconductor region having a first end coupled to the first electrical terminal and a second end coupled to the second terminal, wherein a conductive silicide line is formed in the region when a threshold current between the first and second terminals in reached, the silicide line thereby functioning to prevent electrical damage to the active circuit by discharging charge built up on an external object coming into proximate disposition to the substrate.

In some embodiments, the semiconductor substrate is n-conductivity type silicon, the shunting semiconductor region is composed of p+ conductivity type silicon having a first resistance range for current flow through the element up to a predetermined current threshold, and operating so that if the current flow through the shunting region exceeds the predetermined current threshold, the resistance of the shunting region will drop substantially below that of the first resistance range.

In some embodiments, the shunting region is a channel disposed in the semiconductor substrate in which is formed an electromigration induced conductive silicide line as a function of applied current through the channel.

In some embodiments, the first electrical terminal is composed of nickel or copper, and the second electrical terminal is composed of nickel or copper.

In some embodiments, the semiconductor substrate is composed of n conductivity type silicon.

In some embodiments, the channel is between 150 and 200 micrometers long and between 0.5 and 1.5 micrometers wide, the silicide line is composed of nickel silicide and between 0.5 and 1 micron in width, and about 0.5 micron in depth.

Some implementations of the present disclosure may incorporate or implement fewer of the aspects and features noted in the foregoing summaries.

Additional aspects, advantages, and novel features of the present disclosure will become apparent to those skilled in the art from this disclosure, including the following detailed description as well as by practice of the disclosure. While the disclosure is described below with reference to preferred embodiments, it should be understood that the disclosure is not limited thereto. Those of ordinary skill in the art having access to the teachings herein will recognize additional applications, modifications and embodiments in other fields, which are within the scope of the disclosure as disclosed and claimed herein and with respect to which the disclosure could be of utility.

### BRIEF DESCRIPTION OF THE DRAWINGS

The invention will be better and more fully appreciated by reference to the following detailed description when considered in conjunction with the accompanying drawings, wherein:

FIG. 1 is a schematic diagram of a shunt in accordance with an illustrated embodiment of the disclosure;

FIG. 2 is a graph of the current-voltage (I-V) curve on an illustrated test structure of FIG. 1 at various temperature levels;

FIG. 3 is a plot of the resistance of the silicide line test structure of FIG. 1 as function of current (I);

FIG. 4A is a graph that shows the length of the silicide line as a function of applied current;

FIG. 4B is a graph that shows the resistance reduction in the channel as a function of the length of the silicide line; and

FIG. 5 is a highly simplified schematic diagram of an implementation of the structure of FIG. 1 is an integrated circuit semiconductor device.

### DETAILED DESCRIPTION OF AN ILLUSTRATED EMBODIMENT

Details of the present disclosure will now be described, including exemplary aspects and embodiments thereof. Referring to the drawings and the following description, like reference numbers are used to identify like or functionally similar elements, and are intended to illustrate major features of exemplary embodiments in a highly simplified diagrammatic manner. Moreover, the drawings are not intended to depict every feature of actual embodiments nor the relative dimensions of the depicted elements, and are not drawn to scale.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

In one embodiment, the present disclosure provides electrically an adjustable or tunable Si/silicide shunt or electrical coupling for use in silicon (Si) photonics and hybrid Si/III-V compound semiconductor photonic integrated circuits. The fundamental principle of implementation of the shunt is based on electromigration-induced silicide line formation in a p+-Si channel formed in the silicon substrate. In some embodiments, the choice of the metal contact to the channel includes nickel (Ni) and copper (Co). Other suitable metals may also be used. For the case of Ni contact, the silicide line consists of epitaxial nickel silicide. The shunt can be integrated into the silicon chip and/or adjoined with a III-V compound semiconductor device such as an electro-optical device, e.g. a laser or optical modulator.

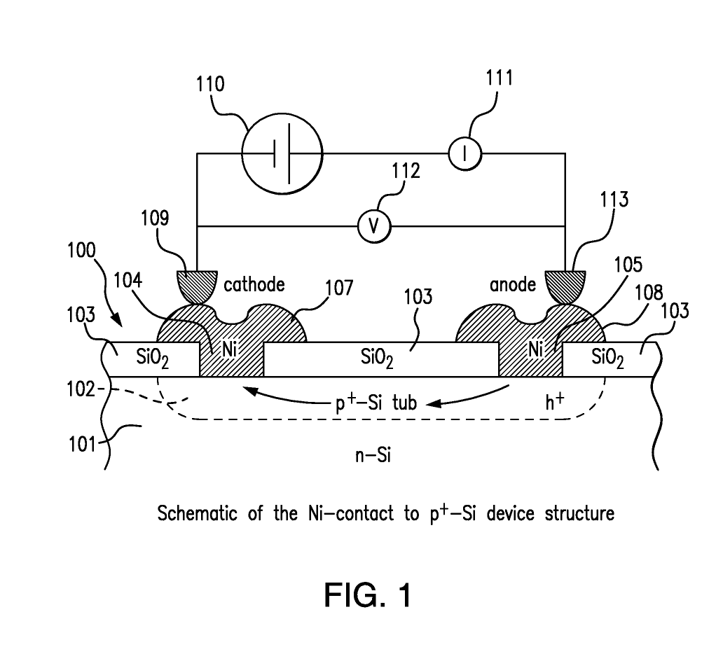

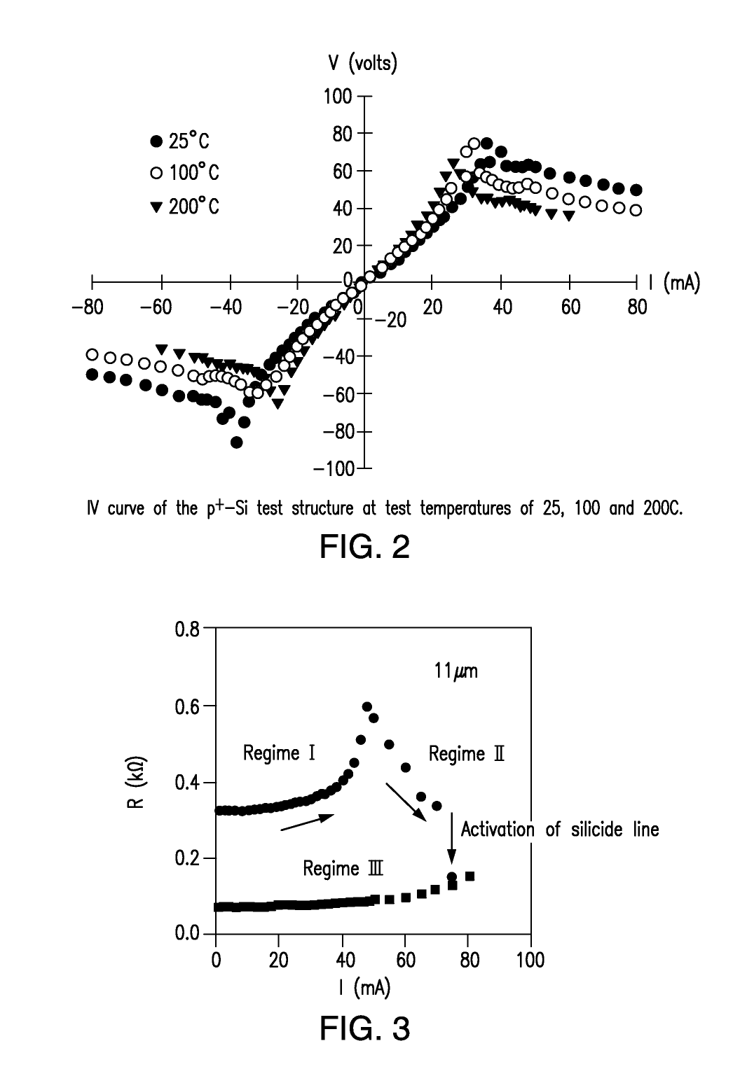

FIG. 1 shows a simplified cross-sectional view of a silicide channel structure based on nickel metal contact to p+ type conductivity silicon semiconductor substrate utilized in embodiments of the present disclosure. In some embodiments, the depicted structure may be fabricated by starting with a (100) n-Si wafer 101 which is deposited with a 300 nm thick Sift dielectric layer. Photolithography and buffered HF acid are then used to define the silicon channel regions 102 in the oxide. A screen oxide of with a typical thickness of 20 nm may be grown for capping and filtering during the subsequent ion implantation steps.

In some embodiments, the n-Si wafer was implanted with a dose of 5×10¹⁵ ions/cm² of boron difloride accelerated to 40 keV without removing the capping oxide. In some embodiments, post-implantation annealing at 900 degrees Centigrade for 30 minutes in a nitrogen ambient atmosphere is carried out to activate the borant dopant.

Following ion implantation, another 300 nm low temperature oxide layer 103 was grown on the silicon substrate 102. A pair of contact windows 104, 105 were opened through the oxide layer 103 by photolithography and buffered HF etch. Finally, a 260 nm thick metal film which may be composed of (Ni, Co, Ti, Al or Cu) was deposited to make ohmic contacts to the p+-Si. The metal bondpads 107, 108 were defined by photolithography and finished by the lift-off process.

For the specific embodiment of the present disclosure, for a p+-Si shunt, nickel (Ni) or copper (Co) metal contact materials were chosen to facilitate effective silicide line formation and resistance reduction.

FIG. 3 shows a graphic representation resistance (R) vs. current (I) curve of the p+-Si channel in a specific embodiment of a channel that is configured as 175 micrometer long and 11 micrometer wide. The resistance curve exhibits three different regimes. In the region which is labeled “Regime I”, the resistance increased gradually in a non-ohmic manner and reaches a maximum value defined as the “critical current”. In the region labeled “Regime II”, the resistance decreases gradually to below the original value. At the critical value of the “activation current”, the resistance decreases precipitously due to silicide line formation and the resistance follows the curve depicted in Regime III.

The embodiment of the specific channel configuration and dimensions is merely illustrative, and other configurations and dimensions may be designed and determined for specific applications or requirements.

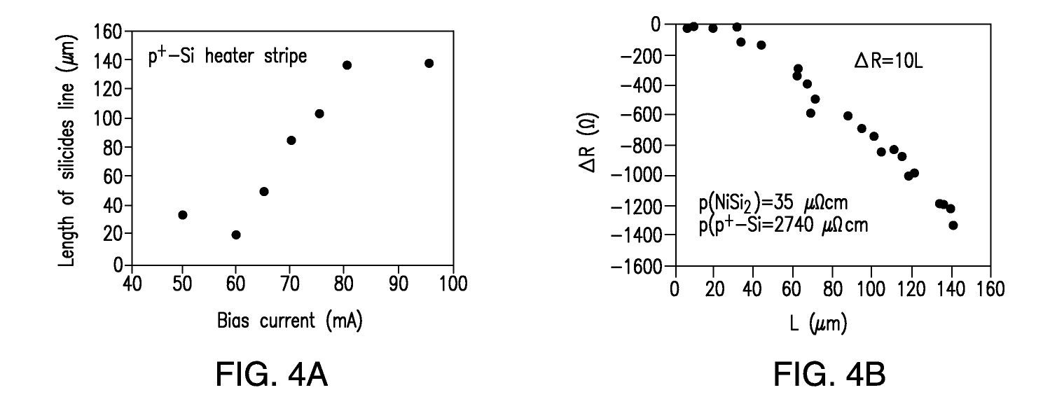

FIG. 4A shows a graph depicting the length of silicide line as a function of applied current for the illustrated embodiment. The silicide line increases linearly with increasing current between 60 and 80 mA. Above 80 mA, the silicide line reaches the maximum length where the line nearly connects the anode and the cathode contacts. FIG. 4B shows the resistance reduction in the material as a result of silicide line formation. In the depicted embodiment, the resistance of the channel decreases by about 10 ohms for each micrometer formation of NiSi2 line.

The use of a p+-Si channel stripe or shunt with silicide line formation has a variety of broad applications in semiconductor devices in which one or more operational parameters of the semiconductor device is desired to be electrically controlled by adjusting the resistance of an element in the device, including electro-optical devices such as lasers, modulators and other photonic devices. Such control may be performed at the time of manufacturing, thereby adjusting the specific parameters of manufactured batches, in the field during deployment and installation, or subsequently when the device is in operation and use by an end-user.

FIG. 4B is a graph that shows the resistance reduction in the channel as a function of the length of the silicide line.

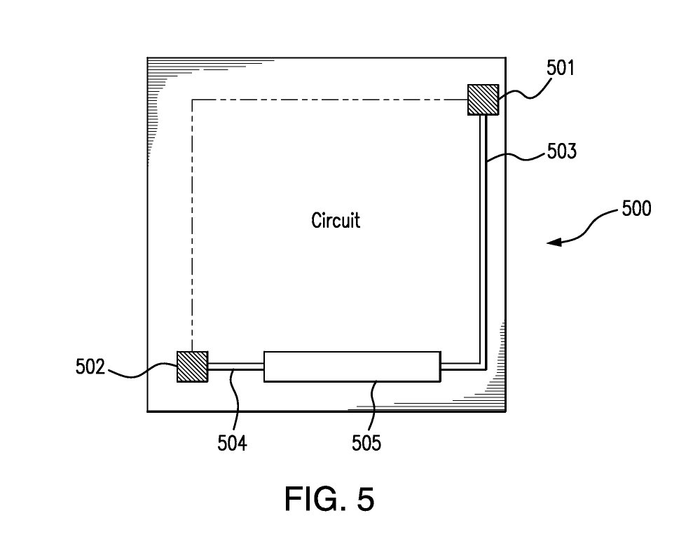

FIG. 5 is a highly simplified schematic diagram of an implementation of the structure of FIG. 1 is an integrated circuit semiconductor device 500. The device 500 has terminals 501 and 502 of opposite polarity (e.g., 501 may be positive voltage, and 502 may be ground). The shunt 505 of FIG. 1 may be connected via trace 503 and terminal 501, and trace 504 to terminal 502.

The embodiment of the specific integrated circuit semiconductor device 500 including the placement, configuration and relative dimensions of the channel is merely illustrative, and other configurations and dimensions may be designed and determined for specific circuits, and their applications or requirements.

In the present disclosure, we present the fabrication of a shunt 505 utilizing a silicide line in the silicon device 500 to enable adjustable bypass of electrical current. An electromigration-induced silicide line is formed in the channel between the first and the second electrical terminals 501 and 502 when the applied current to the terminals increases.

The length and width of the channel may depend on various factors, including the type of semiconductor material and the dopants, and the specific application and electrical requirements of the shunt or channel. In some embodiments, the channel is between 150 and 200 micrometers long and between 1 and 10 micrometers wide. In other embodiments, the channel is between 150 and 200 micrometers long and between 0.5 and 1.5 micrometers wide.

In some embodiments, the applied current is between 60 and 90 mA. In other embodiments, the applied current is between 70 and 80 mA. In yet other embodiments, the applied current is about 80 mA.

In some embodiments the silicide line is between 1 and 2 microns in width, and less than one micron in depth. In other embodiments the silicide line is between 0.5 and 1 microns in width, and less than one-half micron in depth. In yet other embodiments the silicide line is about 0.5 micron in width, and about 0.5 micron in depth.

The foregoing described embodiments depict different components contained within, or connected with, different other components. It is to be understood that such depicted arrangements or architectures are merely exemplary, and that in fact many other arrangements or architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of specific structures, architectures or intermedial components. Likewise, any two components so associated can also be viewed as being “operably connected” or “operably coupled” to each other to achieve the desired functionality.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” “comprise” and variations thereof, such as, “comprises” and “comprising” are to be construed in an open, inclusive sense, that is as “including, but not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations).

Spatially relative terms such as “under”, “below”, “lower”, “over”, “upper”, and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting.

Without further analysis, from the foregoing others can, by applying current knowledge, readily adapt the disclosed technology for various applications. Such adaptations should and are intended to be comprehended within the meaning and range of equivalence of the following claims.

1. A semiconductor device comprising:
a n-conductivity type silicon semiconductor substrate having a surface including an active semiconductor device;
a p-conductivity type region disposed in the semiconductor substrate having a first end and a second end forming a channel there between;
a first electrical terminal composed of nickel or copper disposed on the first end semiconductor substrate;
a second electrical terminal composed of nickel or copper disposed on the second end semiconductor substrate; and
wherein an electromigration-induced silicide line is formed in the channel between the first and the second electrical terminal when the applied current to the terminals increases.

2. A device as defined in claim 1, wherein the channel is between 150 and 200 micrometers long and between 5 and 15 micrometers wide.

3. A device as defined in claim 1, wherein the applied current is between 60 and 90 mA.

4. A device as defined in claim 1, wherein the silicide line is between 1 and 2 microns in width, and less than one micron in depth.

5. A semiconductor device comprising:
a semiconductor substrate having a surface including an active circuit;
a first electrical test point disposed in the circuit on the semiconductor substrate;
a second electrical test point disposed in the circuit on the semiconductor substrate; and
a shunting element composed of p+ conductivity type silicon disposed on the semiconductor substrate having a first end coupled to the first electrical test point and a second end coupled to the second test point, the shunting element having a first resistance range for current flow through the element up to a predetermined current threshold, and operate so that if the current flow through the shunting element exceeds the predetermined threshold, the resistance of the shunting element will drop substantially below that of the first resistance range.

6. A device as defined in claim 5, wherein the shunting element is a channel disposed in the semiconductor substrate in which is formed an electromigration induced conductive silicide line as a function of applied current through the channel.

7. A device as defined in claim 5, further comprising a first electrical terminal composed of nickel or copper disposed at the first test point and a second electrical terminal composed of nickel or copper disposed at the second test point.

8. A device as defined in claim 5, wherein the semiconductor substrate is composed of n conductivity type silicon.

9. A device as defined in claim 6, wherein the channel is between 150 and 200 micrometers long and between 5 and 15 micrometers wide.

10. A device as defined in claim 5, wherein the applied current is between 60 and 90 mA.

11. A device as defined in claim 6, wherein the silicide line is between 1 and 2 microns in width, and less than one micron in depth.

12. A semiconductor device comprising:
a semiconductor substrate having a surface including an active circuit;
a first electrical terminal of a first polarity disposed in the circuit on the semiconductor substrate;
a second electrical terminal of a second polarity disposed in the circuit on the semiconductor substrate; and
a shunting semiconductor region disposed on the semiconductor substrate in a parallel electrical circuit to the active circuit, the shunting semiconductor region having a first end coupled to the first electrical terminal and a second end coupled to the second terminal, wherein a conductive silicide line is formed in the region when a threshold current between the first and second terminals in reached, the silicide line thereby functioning to prevent electrical damage to the active circuit by discharging charge built up on an external object coming into proximate disposition to the substrate.

13. A device as defined in claim 12, wherein the semiconductor substrate is n-conductivity type silicon, the shunting semiconductor region is composed of p+ conductivity type silicon having a first resistance range for current flow through the element up to a predetermined current threshold, and operating so that if the current flow through the shunting region exceeds the predetermined current threshold, the resistance of the shunting region will drop substantially below that of the first resistance range.

14. A device as defined in claim 12, wherein the shunting region is a channel disposed in the semiconductor substrate in which is formed an electromigration induced conductive silicide line as a function of applied current through the channel.

15. A device as defined in claim 12, wherein the first electrical terminal is composed of nickel or copper, and the second electrical terminal is composed of nickel or copper.

16. A device as defined in claim 12, wherein the semiconductor substrate is composed of n conductivity type silicon.

17. A device as defined in claim 12, wherein the channel is between 150 and 200 micrometers long and between 5 and 15 micrometers wide.

18. A device as defined in claim 12, wherein the applied current is between 60 and 90 mA.

19. A device as defined in claim 12, wherein the silicide line is between 1 and 2 microns in width, and less than one micron in depth.

20. A device as defined in claim 12, wherein the channel is between 150 and 200 micrometers long and between 5 and 15 micrometers wide, the silicide line is composed of nickel silicide and between 1 and 2 microns in width, and less than one micron in depth.
